(19) United States
(12) Patent Application Publication
(10) Pub. No.: US 2024/0421012 A1
(43) Pub. Date: Dec. 19, 2024

(54) SEMICONDUCTOR DEVICE

(71) Applicant: SAMSUNG ELECTRONICS CO., LTD., Suwon-si (KR)

(72) Inventors: Sangsick PARK, Suwon-si (KR); Chungsun LEE, Suwon-si (KR); Hanmin LEE, Suwon-si (KR); Seungyoon JUNG, Suwon-si (KR)

(21) Appl. No.: 18/210,134

(22) Filed: Jun. 15, 2023

(30) Foreign Application Priority Data
Jul. 19, 2022 (KR) 10-2022-0089030

(51) Int. Cl. H01L 23/24; H01L 23/00; H01L 25/065

(52) U.S. Cl. CPC H01L 23/24; H01L 24/16; H01L 24/32; H01L 24/73; H01L 25/0657; H01L 2224/16148; H01L 2224/16227; H01L 2224/32145; H01L 2224/32225; H01L 2224/73204; H01L 2225/06513; H01L 2225/06517; H01L 2225/06544; H01L 2924/3511

(57) ABSTRACT

A semiconductor device includes a first semiconductor chip having a first through silicon via (TSV). A second semiconductor chip is arranged on the first semiconductor chip and includes a second TSV positioned on a same vertical line as the first TSV. A conductive pad is disposed on each of the first TSV and the second TSV. The conductive pad electrically connects the first semiconductor chip and the second semiconductor chip to each other. A warpage prevention metal structure is disposed on an upper surface of the first semiconductor chip or an upper surface of the second semiconductor chip.

### CROSS-REFERENCE TO RELATED APPLICATION

This application claims priority under 35 U.S.C. § 119 to Korean Patent Application No. 10-2022-0089030, filed on Jul. 19, 2022 in the Korean Intellectual Property Office, the disclosure of which is incorporated by reference in its entirety herein.

### 1. TECHNICAL FIELD

The present inventive concept relates to a semiconductor device, and more particularly, to a semiconductor package device.

### 2. DISCUSSION OF RELATED ART

There has been a growing demand for a technology for stacking multiple semiconductor chips in the electronic industry due to the demand for high bandwidth and high capacity semiconductor devices. One process among various technologies for stacking multiple semiconductor chips may be referred to as a bonding process for multiple semiconductor chips. However, in the process of bonding multiple semiconductor chips, in particular, in the process of bonding a semiconductor chip having a Through Silicon Via (TSV), since forces are concentrated on the TSV, conductive pads, and micro bumps, the semiconductor chip may be bent during the bonding process. Also, warpage may occur due to an increase in the temperature of the semiconductor chip.

### SUMMARY

An embodiment of the present inventive concept relates to a semiconductor device capable of preventing warpage of a semiconductor chip.

The objectives to be solved by embodiments of the present inventive concept are not limited to the above-mentioned ones, and other objectives not mentioned herein will be clearly understood by those skilled in the art from the following description.

According to an embodiment of the present inventive concept, a semiconductor device includes a first semiconductor chip having a first through silicon via (TSV). A second semiconductor chip is arranged on the first semiconductor chip and includes a second TSV positioned on a same vertical line as the first TSV. A conductive pad is disposed on each of the first TSV and the second TSV. The conductive pad electrically connects the first semiconductor chip and the second semiconductor chip to each other. A warpage prevention metal structure is disposed on an upper surface of the first semiconductor chip or an upper surface of the second semiconductor chip.

According to an embodiment of the present inventive concept, a semiconductor device includes a plurality of inner substrates including semiconductor devices. A through silicon via (TSV) is arranged to vertically penetrate each of the plurality of inner substrates. A protective layer is disposed on an upper surface of each of the plurality of inner substrates. The protective layer surrounds a side surface of the TSV. A conductive pad is arranged on the TSV. A warpage prevention metal structure is disposed on the protective layer of some of the plurality of inner substrates. The warpage prevention metal structure is electrically insulated from the semiconductor devices of the plurality of inner substrates.

According to an embodiment of the present inventive concept, a semiconductor device includes a plurality of inner substrates including semiconductor devices. A through silicon via (TSV) is arranged to vertically penetrate each of the plurality of inner substrates. A protective layer is disposed on an upper surface of each of the plurality of inner substrates. The protective layer surrounds a side surface of the TSV. A conductive pad is disposed on the TSV. A warpage prevention metal structure is disposed on the protective layer of an upper inner substrate or a lower inner substrate based on a virtual horizontal line dividing the plurality of inner substrates in a vertical direction. The warpage prevention metal structure is electrically insulated from the semiconductor devices of the plurality of inner substrate. An upper substrate is arranged on an upper portion of each of the plurality of inner substrates. The upper substrate is electrically connected to an uppermost inner substrate among the plurality of inner substrates through the conductive pad. The upper substrate has a thickness greater than thicknesses of each of the plurality of inner substrates.

### BRIEF DESCRIPTION OF THE DRAWINGS

Embodiments of the present inventive concept will be more clearly understood from the following detailed description taken in conjunction with the accompanying drawings in which:

FIGS. 1A and 1B are side cross-sectional views illustrating a semiconductor device according to embodiments of the present inventive concept;

FIG. 1C is a side cross-sectional view illustrating a semiconductor device according to an embodiment of the present inventive concept;

FIG. 2 is a side cross-sectional view taken along plane AA of FIG. 1B according to an embodiment of the present inventive concept;

FIGS. 3A and 3B are cross-sectional views schematically illustrating a case in which warpage occurs in a semiconductor device;

FIG. 4 is an enlarged side cross-sectional view of a portion of a semiconductor device according to an embodiment of the present inventive concept;

FIG. 5 is an enlarged side cross-sectional view of a portion of a semiconductor device according to an embodiment of the present inventive concept;

FIGS. 6A to 6E are side cross-sectional views illustrating a method of manufacturing a semiconductor device according to embodiments of the present inventive concept;

FIG. 7 is a side cross-sectional view illustrating a semiconductor device according to an embodiment of the present inventive concept;

FIG. 8 is a plan view illustrating an X-Y plane between a semiconductor chip 200 and a semiconductor chip 210 when viewed in the −Z-axis direction in the semiconductor device of FIG. 7 according to an embodiment of the present inventive concept;

FIG. 9 is a plan view of a semiconductor device according to an embodiment of the present inventive concept when viewed in the −Z-axis direction at the same position as shown in FIG. 8;

FIG. 10 is a plan view of a semiconductor device according to an embodiment of the present inventive concept when viewed in the −Z-axis direction at the same position as shown in FIG. 8;

FIG. 11 is a plan view of a semiconductor device according to an embodiment of the present inventive concept when viewed in the −Z-axis direction at the same position as shown in FIG. 8;

FIG. 12 is a plan view of a semiconductor device according to an embodiment of the present inventive concept when viewed in the −Z-axis direction at the same position as shown in FIG. 8;

FIG. 13 is a plan view of a semiconductor device according to an embodiment of the present inventive concept when viewed in the −Z-axis direction at the same position as shown in FIG. 8;

FIG. 14 is a plan view of a semiconductor device according to an embodiment of the present inventive concept when viewed in the −Z-axis direction at the same position as shown in FIG. 8;

FIG. 15 is a plan view of a semiconductor device according to an embodiment of the present inventive concept when viewed in the −Z-axis direction at the same position as shown in FIG. 8;

FIG. 16 is a plan view of a semiconductor device according to an embodiment of the present inventive concept when viewed in the −Z-axis direction at the same position as shown in FIG. 8; and

FIG. 17 is a plan view of a semiconductor device according to an embodiment of the present inventive concept when viewed in the −Z-axis direction at the same position as shown in FIG. 8.

### DETAILED DESCRIPTION OF EMBODIMENTS

Example embodiments of the present inventive concept are provided to more completely describe the present inventive concept to those skilled in the art in a technological field to which the present inventive concept belongs, and the following embodiments may be modified in various different forms, and the scope of the present inventive concept is not limited to the following embodiments.

A semiconductor chip, which has undergone an overall process of forming a circuit on a wafer, may undergo a post-process performed by a package and a test. Although micro-electric circuits are integrated in semiconductor chips, it is difficult to perform the role of semiconductors only with semiconductor chips. The package process may serve to electrically connect the chip to the outside and protect the chip from the external environment, so that the chip may serve as its function. In addition, heat emitted from the semiconductor may be efficiently discharged through the package.

The semiconductor package may serve as mechanical protection, electrical connection, mechanical connection, heat dissipation, and the like. For example, the semiconductor chip may be protected from external mechanical and chemical impacts with a package material such as an epoxy mold compound (EMC). Through the package, the semiconductor chip may be physically and electrically connected to a system to supply power for the semiconductor chip to operate. In addition, signals are input to and output from the semiconductor chip so that the semiconductor chip may perform desired functions, and heat generated when the semiconductor product operates may be emitted.

A method of packaging a semiconductor may be classified into a conventional package that applies a packaging process to an individual chip separated from a wafer, and a wafer level package (WLP) in which a process is partially or entirely performed in a wafer stage and a wafer is cut into chips at a later stage.

The initial packaging technology was a lead frame method that connects chips and pads with metal wires (e.g., gold wires). However, as the performance requirement of the device has increased, there is a limit to the lead frame structure, and thus, a fine-pitch ball grid array (fBGA) based on a substrate on which the fine pattern is engraved is applied. Such a conventional package may be capable of accumulating a large amount of chips in a package and thus may be mainly applied to NAND or mobile DRAM which places emphasis on a high capacity.

To meet the requirements of a memory product, a conventional package which is an existing traditional method is being developed, and simultaneously a WLP which is a new method is being introduced. The WLP is a technology suitable for implementing high-performance products and may be packaged in the same chip size. Therefore, the size of semiconductor finished products may be reduced, and since materials such as substrates and wires are not included, cost may be reduced. The WLP processes may be utilized in products such as high bandwidth memory (HBM) or high-capacity computing DRAM. The HBM is a 3D memory semiconductor that connects several DRAMs vertically. When the semiconductor device including the HBM is heated, a warpage may occur. To solve the above problem, a semiconductor device according to an embodiment of the present inventive concept will be described in detail with reference to the accompanying drawings.

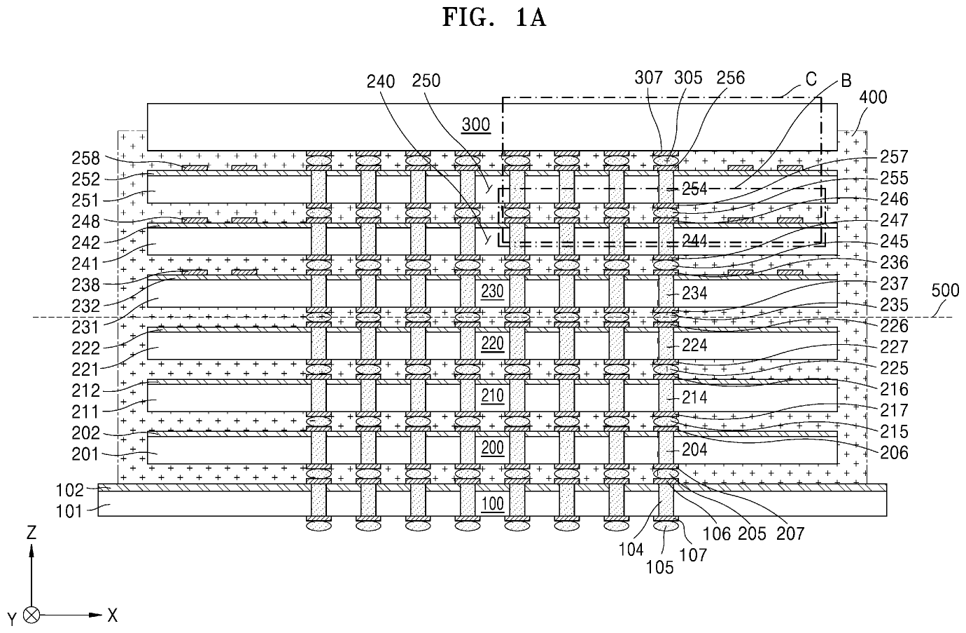

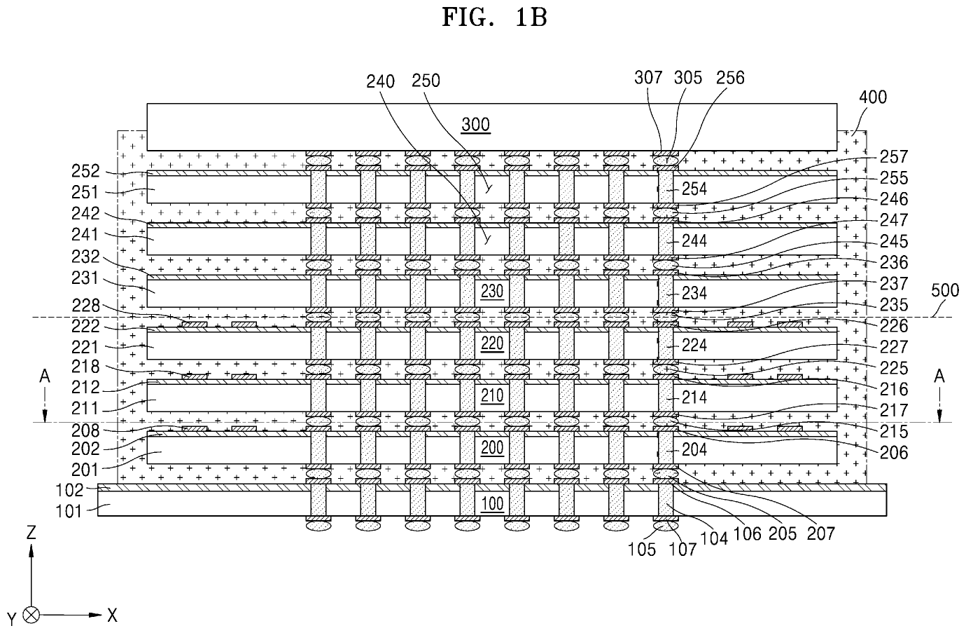

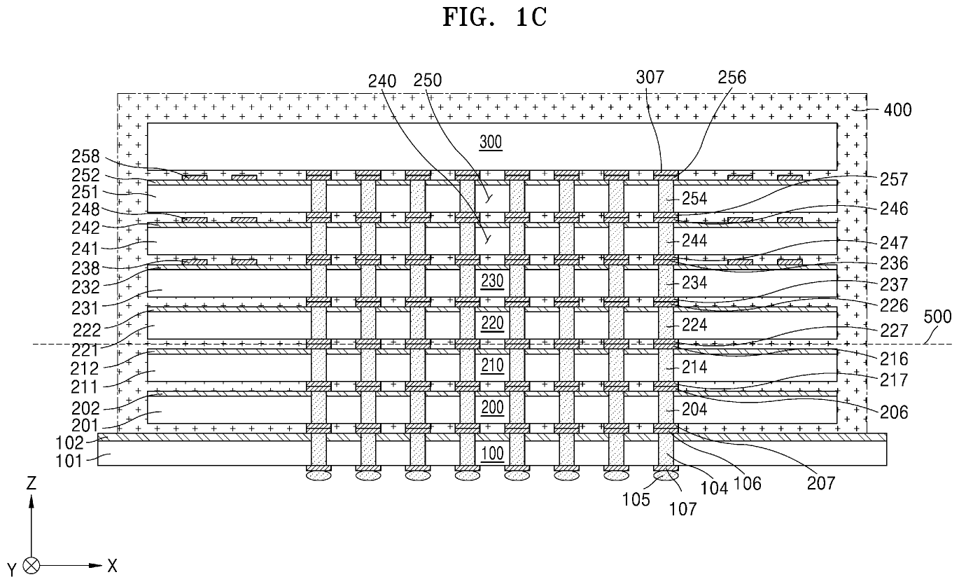

FIGS. 1A and 1B are side cross-sectional views schematically illustrating a semiconductor device according to embodiments of the present inventive concept.

Referring to FIGS. 1A and 1B, the semiconductor device according to an embodiment includes a substrate 100, a plurality of semiconductor chips 200, 210, 220, 230, 240, and 250, and an upper semiconductor chip 300. The substrate 100 may be a silicon substrate based on a semiconductor wafer. In an embodiment, the substrate 100 may be a package substrate, and may be a printed circuit board (PCB). The substrate 100 includes upper and lower surfaces corresponding to each other. A conductive bump 105 may be disposed on a lower surface of the substrate 100 to electrically connect the semiconductor device according to various embodiments to an external device. Electrical signals may be supplied to the plurality of semiconductor chips 200, 210, 220, 230, 240, and 250 and upper semiconductor chip 300 through the conductive bump 105. At least one of upper conductive pads 106 may be a ground pad and may be electrically connected to a ground line in the substrate 100.

The plurality of semiconductor chips 200, 210, 220, 230, 240, and 250 are arranged on the substrate 100. For example, the plurality of semiconductor chips 200, 210, 220, 230, 240, and 250 may be sequentially stacked in a vertical direction (e.g., in the Z direction) to form a stacked structure. While embodiments in FIGS. 1A-1B show the plurality of semiconductor chips 200, 210, 220, 230, 240 and 250 including six semiconductor chips, embodiments of the present inventive concept are not necessarily limited thereto and the number of semiconductor chips may vary. In an embodiment, the plurality of semiconductor chips 200, 210, 220, 230, 240, and 250 may include a memory chip, a logic chip, etc. For example, in an embodiment in which at least one of the plurality of semiconductor chips 200, 210, 220, 230, 240, and 250 is a logic chip, the at least one of the plurality of semiconductor chips 200, 210, 220, 230, 240, and 250 may be variously designed according to an operation to be performed. In an embodiment in which at least one of the plurality of semiconductor chips 200, 210, 220, 230, 240, and 250 is a memory chip, the memory chip may be, for example, a nonvolatile memory chip. For example, the memory chip may be a flash memory chip. The memory chip may be any one of a NAND flash memory chip and a NOR flash memory chip. However, the form of the memory device according to embodiments of the present inventive concept are not necessarily limited thereto. For example, in an embodiment of the present inventive concept, the memory chip may include any one of a phase change random access memory (PRAM), a magneto-resistive random access memory (MRAM), a resistive random access memory (RRAM), and a dynamic random access memory (DRAM).

The semiconductor chip 200 may be electrically connected to the substrate 100 by a lower conductive pad 207 disposed on a lower surface of the semiconductor chip 200. For example, the lower conductive pad 207 may electrically connect the semiconductor chip 200 with the upper conductive pad 106 of the substrate 100. In some embodiments, a conductive bump 205 may be disposed between the lower conductive pad 207 and the upper conductive pad 106 to mediate an electrical connection between the lower conductive pad 207 and the upper conductive pad 106. In embodiments shown in FIGS. 1A-1B, the bump 205 is illustrated as a ball-shaped solder ball. However, embodiments of the present inventive concept are not necessarily limited thereto.

An under fill material 400 filling a space between the substrate 100 and the semiconductor chip 200 may be disposed between the substrate 100 and the semiconductor chip 200. In an embodiment, the under fill material 400 may surround at least a portion of the side surface of the semiconductor chip 200, or may surround peripheral portions of the plurality of semiconductor chips 200, 210, 220, 230, 240, and 250. The under fill material 400 may include a non-conductive material through which electricity is not conducted. For example, in an embodiment the under fill material 400 may be a non-conductive film (NCF), a die attach film (DAF), or the like. However, embodiments of the present inventive concept are not necessarily limited thereto.

The semiconductor chip 200 includes an inner substrate 201 including semiconductor devices, a through silicon via (TSV) 204, and a protective layer 202. The inner substrate 201 may be a silicon substrate like the substrate 100.

At least a portion of the TSV 204 disposed in the semiconductor chip 200 is arranged to vertically penetrate the inner substrate 201. As an embodiment, the TSV 204 may be arranged to protrude from the upper surface of the inner substrate 201 (e.g., in the Z direction). A side surface of the protruding TSV 204 may be surrounded by the protective layer 202 disposed on an upper surface of the inner substrate 201.

In an embodiment, the TSV 204 may include at least one metal. For example, the TSV 204 may include a wiring metal layer positioned at the center thereof and a barrier metal layer disposed outside the wiring metal layer. In an embodiment, the wiring metal layer may include at least one compound selected from aluminum (Al), gold (Au), beryllium (Be), bismuth (Bi), cobalt (Co), copper (Cu), hafnium (Hf), indium (In), manganese (Mn), molybdenum (Mo), nickel (Ni), palladium (Pd), platinum (Pt), rhodium (Rh), rhenium (Re), ruthenium (Ru), tantalum (Ta), tellurium (Te), titanium (Ti), tungsten (W), zinc (Zn), and zirconium (Zr), and the barrier metal layer may include a stack structure of one or more selected from titanium (Ti), tantalum (Ta), titanium nitride (TiN), and tantalum nitride (TaN).

One or more upper conductive pads 206 may be disposed on the upper surface of the semiconductor chip 200. The upper conductive pad 206 disposed on the upper surface of the semiconductor chip 200 may be electrically connected to the semiconductor chip 210 arranged on the semiconductor chip 200. For example, the upper conductive pad 206 may connect the TSV 204 disposed in the semiconductor chip 200 with the semiconductor chip 210. A conductive bump 215 is disposed between the upper conductive pad 206 and the semiconductor chip 210 to mediate an electrical connection between the upper conductive pad 206 and the semiconductor chip 210. In an embodiment, the conductive bump 215 may be a micro bump. However, embodiments of the present inventive concept are not necessarily limited thereto.

The upper conductive pad 206 may be disposed on the upper surface of the TSV 204 and may overlap a portion of the protective layer 202 (e.g., in the Z direction). For example, the lower surface of the upper conductive pad 206 may directly contact both the upper surface of the TSV 204 and at least a portion of the upper surface of the protective layer 202. In some embodiments, the upper conductive pad 206 may include a metal. For example, in an embodiment the upper conductive pad 206 may be a plating pad formed by plating, and may include any one of Au, Ni/Au, and Ni/Pd/Au.

A warpage prevention metal structure 208 may be disposed on the semiconductor chip 200. The protective layer 202 may be disposed between the semiconductor chip 200 and the warpage prevention metal structure 208 (e.g., in the Z direction). FIG. 1A illustrates an embodiment in which the metal structure 208 for preventing a warpage is not disposed on the semiconductor chip 200, and FIG. 1B illustrates an embodiment in which the metal structure 208 for preventing the warpage is disposed on the semiconductor chip 200. The shape of the warpage prevention metal structure 208 may be the same as or different from the shape of the upper conductive pad 206. A manufacturing method when the shapes are the same or different will be described later. Since the warpage prevention metal structure 208 is disposed on the protective layer 202, the warpage prevention metal structure may not be electrically connected to the inner substrates including the semiconductor devices. In addition, in an embodiment in which there is no protective layer 202 disposed on an upper surface of the inner substrate 201, the warpage prevention metal structure 208 may be insulated and not be electrically connected to inner substrates including the semiconductor devices. In an embodiment, the warpage prevention metal structure 208 may include the same material as the upper conductive pad 206. The TSV 204 may not be disposed below the warpage prevention metal structure 208.

The semiconductor chips 210, 220, 230, 240, and 250 arranged on the semiconductor chip 200 may be formed similarly to the semiconductor chip 200 described above. For example, the semiconductor chips 200, 210, 220, 230, 240, and 250 may be electrically connected by the lower conductive pads 217, 227, 237, 247, and 257 disposed on the lower surfaces of the semiconductor chips 200, 210, 220, 230, 240, and 250. In this embodiment, the under fill material 400 may be formed around the semiconductor chips 200, 210, 220, 230, 240, and 250. The under fill material 400 may surround a portion of or an entirety of all of the side surfaces of the semiconductor chips 200, 210, 220, 230, 240, and 250.

The semiconductor chips 200, 210, 220, 230, 240, and 250 include inner substrates 201, 211, 221, 231, 241, and 251, TSV 204, 214, 224, 234, 244, and 254, and protective layers 202, 212, 222, 232, 242, and 252, respectively. One or more upper conductive pads 206, 216, 226, 236, 246, and 256 may be arranged on an upper surface of each of the semiconductor chips 200, 210, 220, 230, 240, and 250. In some of the semiconductor chips 200, 210, 220, 230, 240, and 250, one or more warpage prevention metal structures 208, 218, 228, 238, 248, and 258 may be disposed on each of the protective layers 202, 212, 222, 232, 242, and 252.

The various components of the semiconductor chips 210, 220, 230, 240, and 250 correspond to the configurations described with respect to the semiconductor chip 200, and the various configurations of the semiconductor chips 210, 220, 230, 240, and 250 are the same as those described with respect to the semiconductor chip 200. Thus, redundant descriptions of the various configurations of the semiconductor chips 210, 220, 230, 240, and 250 with respect to those described with respect to the semiconductor chip 200 will be omitted for economy of description.

The upper semiconductor chip 300 is arranged on the plurality of semiconductor chips 200, 210, 220, 230, 240, and 250. For example, the upper semiconductor chip 300 may be additionally stacked (e.g., in a Z direction) in a stacked structure consisting of the plurality of semiconductor chips 200, 210, 220, 230, 240, and 250. For example, as shown in FIGS. 1A and 1B, the upper semiconductor chip 300 may be electrically connected to the semiconductor chip 250 located at the uppermost portion of the semiconductor chips through the upper conductive pads 256. A thickness (e.g., length in the Z direction) of the upper semiconductor chip 300 may be greater than a thickness of each of the semiconductor chips 200, 210, 220, 230, 240, and 250. Like the plurality of semiconductor chips 200, 210, 220, 230, 240, and 250, the upper semiconductor chip 300 may include a memory chip, a logic chip, etc.

The under fill material 400 filling a space between the semiconductor chip 250 and the upper semiconductor chip 300 may be disposed between the semiconductor chip 250 and the upper semiconductor chip 300. As described above, the under fill material 400 may surround at least a portion of the side surface of the semiconductor chip 250 and at least a portion of the side surface of the upper semiconductor chip 300. The under fill material 400 may include a non-conductive material through which electricity is not conducted. In an embodiment, the under fill material 400 may be, for example, a non-conductive film (NCF), a die attach film (DAF), or the like. However, embodiments of the present inventive concept are not necessarily limited thereto.

FIG. 1C is a side cross-sectional view illustrating a semiconductor device according to an embodiment of the present inventive concept. In an embodiment, the upper conductive pads 106, 206, 216, 226, 236, 246, and 256 and the lower conductive pads 207, 217, 227, 237, 247, 257, and 307 may be formed of a material including Cu. In an embodiment, the upper conductive pad and the lower conductive pad, which are adjacent to each other, may be bonded to each other by Cu—Cu hybrid bonding. In an embodiment, an insulating layer may be arranged between the upper surface and the lower surface of each of the semiconductor chips bonded to each other by the hybrid bonding. Embodiments of the present inventive concept may also be applied to a semiconductor device having a hybrid bonding structure.

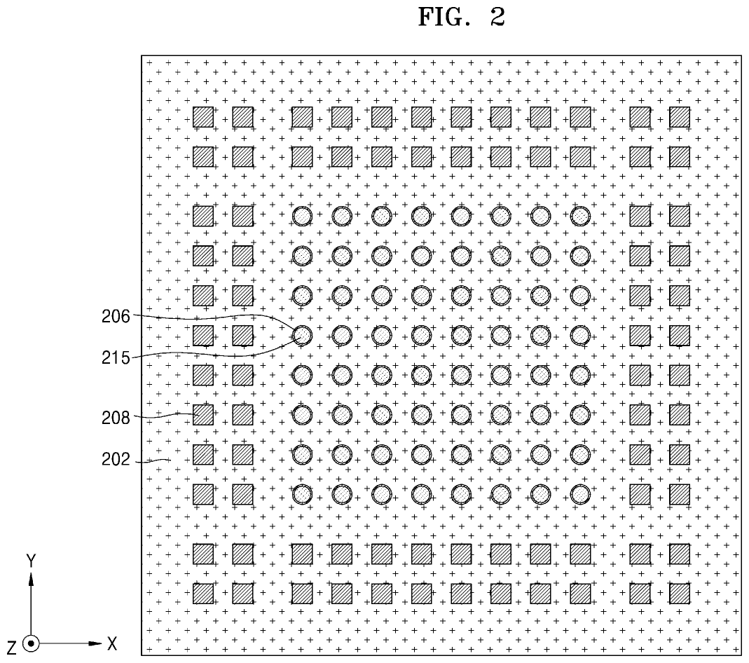

FIG. 2 is a cross-sectional view of plane AA of FIG. 1B when viewed in a −Z-axis direction.

Referring to FIG. 2, a protective layer 202 may be disposed on (e.g., disposed directly thereon in the Z direction) an upper surface of the semiconductor chip 200. A conductive bump 215 for electrically connecting the upper conductive pad 206 electrically connected to the TSV 204 with the lower conductive pad 217 shown in FIGS. 1A and 1B, may be disposed on the protective layer 202. A plurality of the TSVs 204, the upper conductive pads 206, and the conductive bumps 215 may be distributed on the upper surface of the semiconductor chip 200 and may be positioned in the center thereof. In FIG. 2, the semiconductor chip 200 has a shape in a plan view (e.g., in a plane defined in the X and Y directions) of a square, and the upper conductive pad 206 and the conductive bump 215 are distributed in numbers of 64 in a square shape at the center of the semiconductor chip 200. FIG. 2 is an example embodiment, and the arrangement, number, and shape of the TSVs 204, the upper conductive pads 206, and the conductive bumps 215 on the semiconductor chip 200 are not necessarily limited thereto.

The warpage prevention metal structures 208 are arranged in a square and may be disposed on the protective layer 202, along the peripheries of the TSVs 204, the upper conductive pads 206, the lower conductive pads 217, and the conductive bumps 215, and the circumference of the semiconductor chip 200. FIG. 2 is an example embodiment, and the number, shape, and arrangement of the warpage prevention metal structures 208 disposed on one semiconductor chip are not necessarily limited thereto.

The above description of the semiconductor chip 200 may also be applied to the semiconductor chips 210, 220, 230, 240, and 250. Accordingly, redundant descriptions of the semiconductor chips 200, 210, 220, 230, 240, and 250 will be omitted for economy of description.

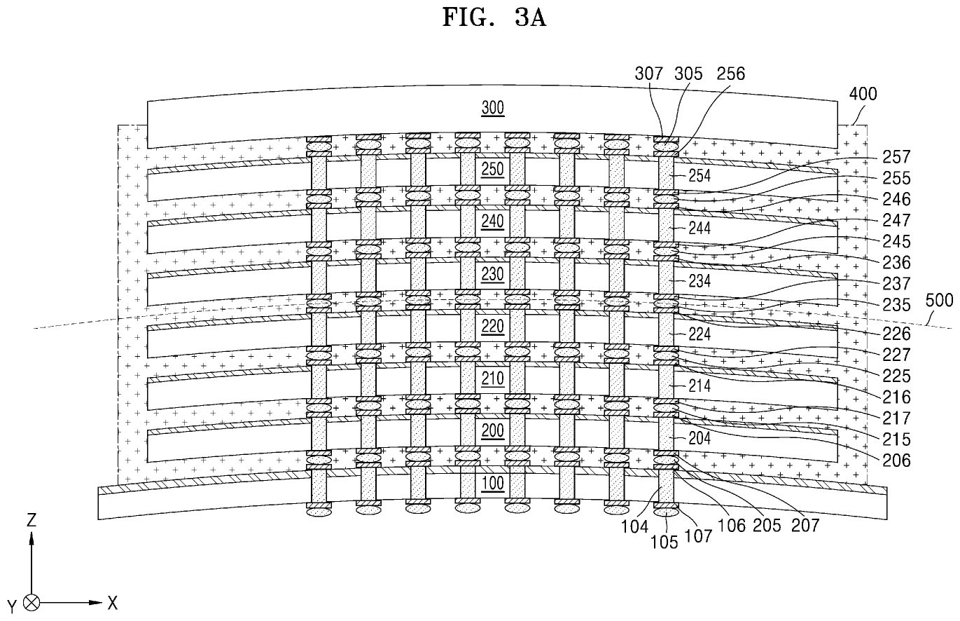

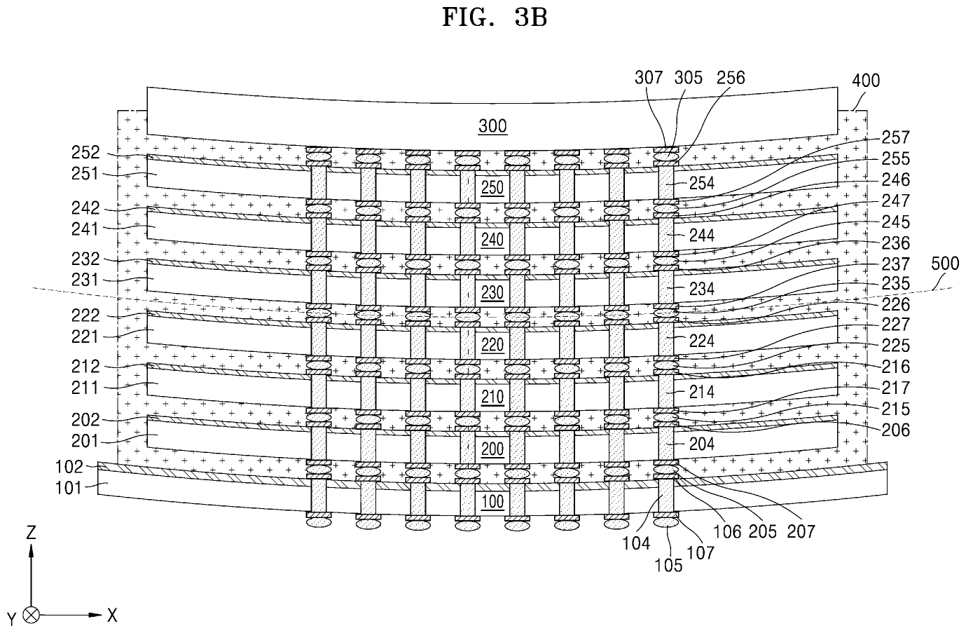

FIGS. 3A and 3B are cross-sectional views schematically illustrating a case in which a warpage occurs in a conventional semiconductor device.

Referring to FIGS. 3A and 3B, a typical semiconductor device may generate a warpage due to a process of stacking by performing thermal compression bonding, or a warpage occurring due to a temperature increase in a process of operating the semiconductor device. The warpage may occur due to differences in thermal expansion coefficients of the components and materials constituting the semiconductor device. As shown in FIG. 3A, a cry-shaped warpage with a shape in which the center of the semiconductor device rises compared to other parts, such as an upward convex shape, may occur due to the temperature increase. Alternatively, the cry-shaped warpage may be expressed as the first semiconductor chips 200, 210, and 220 being convexly bent toward the semiconductor chips 230, 240, and 250. Alternatively, due to the temperature rise, a smile-shaped warpage in which the center of the semiconductor device is lower than other parts, such as a downward convex shape, may occur as shown in FIG. 3B. Alternatively, the smile-shaped warpage may be expressed as the semiconductor chips 230, 240, and 250 being convexly bent toward the semiconductor chips 200, 210, and 220. When warpage occurs in the semiconductor device, stress may occur inside the semiconductor device due to the warpage.

When considering the semiconductor device as a kind of a beam, the warpage of the semiconductor device may be viewed as flexure of the beam or bending of the beam. Stress due to the bending of the beam may occur. The stress caused by the bending of the beam is called bending stress. When the beam is bent, a neutral axis may exist inside the beam. The neutral axis refers to a line that connects parts where tension or compression does not occur when the member forming the beam is compressed or stretched due to the bending of the beam.

The warpage prevention metal structures 208 may be disposed on the upper semiconductor chip or the lower semiconductor chip based on a virtual horizontal line 500, as shown in FIGS. 1A to 1C. The virtual horizontal line 500 may be the neutral axis described above.

In an embodiment, when the virtual horizontal line 500 is a neutral axis, the semiconductor device may receive tensile stress or compressive stress based on the neutral axis. As shown in FIG. 3A, when a cry-shaped warpage with an upward convex shape occurs, the upper semiconductor chips may receive tensile stress based on the virtual horizontal line 500, and the lower semiconductor chips may receive compressive stress based on the virtual horizontal line 500. As shown in FIG. 3B, when a smile-shaped warpage with a downward convex shape occurs, the lower semiconductor chips may receive tensile stress based on the virtual horizontal line 500, and the upper semiconductor chips may receive compressive stress based on the virtual horizontal line 500.

Since the warpage prevention metal structures 208, 218, 228, 238, 248, and 258 are made of metal, the thermal expansion coefficients of the warpage prevention metal structures 208, 218, 228, 238, 248, and 258 may be larger than the overall thermal expansion coefficient of the semiconductor device. When the temperature of the semiconductor device rises, the warpage prevention metal structures 208, 218, 228, 238, 248, and 258 may experience greater thermal expansion than other elements of the semiconductor device. Accordingly, the semiconductor chip to which the warpage prevention metal structures 208, 218, 228, 238, 248, and 258 are attached may receive tensile stress from the warpage prevention metal structure 208 when the semiconductor device is heated.

As shown in FIG. 3A, when a cry-shaped warpage having an upward convex shape occurs, if the virtual horizontal line 500 is a neutral axis, compressive stress may be applied to the semiconductor chip positioned below the virtual horizontal line 500 as described above. As shown in FIG. 1B, the warpage prevention metal structures 208, 218, 228, 238, 248, and 258 may be disposed on the upper surface of the semiconductor chip positioned below the virtual horizontal line 500. As described above, the warpage prevention metal structures 208, 218, 228, 238, 248, and 258 have higher thermal expansion coefficients than other elements of the semiconductor device, and thus may be relatively elongated by the temperature increase. Since the warpage prevention metal structures 208, 218, 228, 238, 248, and 258 are heated and tensile stress is applied to the semiconductor chip, the compressive stress applied to the semiconductor chip located at the lower portion thereof may be reduced. Accordingly, when compared to a semiconductor device in which the warpage prevention metal structures 208, 218, 228, 238, 248, and 258 are not disposed thereon, the semiconductor device in which the warpage prevention metal structures 208, 218, 228, 238, 248, and 258 are disposed thereon may have a reduced degree of occurrence of a warpage.

As shown in FIG. 3B, when a smile-shaped warpage having a downward convex shape occurs, if the virtual horizontal line 500 is a neutral axis, compressive stress may be applied to the semiconductor chip located above the virtual horizontal line 500 as described above. As shown in FIG. 1A, the warpage prevention metal structure may be disposed on the upper surface of the semiconductor chip positioned above the virtual horizontal line 500. As described above, since the warpage prevention metal structure applies tensile stress while extending when compared to the semiconductor chip, the compressive stress due to the temperature rise may be attenuated. Accordingly, when compared to a semiconductor device according to a comparative embodiment in which the warpage prevention metal structure is not disposed thereon, the semiconductor device in which the warpage prevention metal structure is disposed thereon according to an embodiment of the present inventive concept may reduce the degree of generation of a warpage.

As described above, the virtual horizontal line 500 may be a neutral axis in the bending of the beam. However, in some embodiments the virtual horizontal line 500 may be a line that vertically uniformly divides the semiconductor device in a horizontal direction, or may be an arbitrary horizontal line, and thus, the setting of the virtual horizontal line 500 is not necessarily limited by embodiments shown in FIGS. 3A and 3B.

In a further description, when the warpage prevention metal structure is disposed on the upper or lower semiconductor chip with respect to the virtual horizontal line 500, the ratio of the metal may vary at each of the upper portion and the lower portion of the semiconductor device.

When a cry-shaped warpage having an upward convex shape occurs as shown in FIG. 3A, the warpage prevention metal structures 208, 218, and 228 may be disposed on the lower semiconductor chips 200, 210, and 220 based on the virtual horizontal line 500 as shown in FIG. 1B. Based on the virtual horizontal line 500, the lower portion of the semiconductor device may have a relatively higher ratio of metal when compared to the upper portion thereof. Metal has a relatively high thermal expansion coefficient compared to semiconductor devices. Therefore, the lower portion of the semiconductor device has an average thermal expansion coefficient that is higher than the upper portion thereof. For example, when the temperature of the semiconductor device rises, the upper portion of the semiconductor device may be expanded to a greater degree than when the warpage prevention metal structures 208, 218, and 228 are not present. Therefore, when compared to the absence of the warpage prevention metal structures 208, 218, and 228, the degree of warpage generated in the semiconductor device may be reduced, when the warpage prevention metal structures 208, 218, and 228 are present.

When a smile-shaped warpage having a downward convex shape occurs as shown in FIG. 3B, the warpage prevention metal structures 238, 248, and 258 may be disposed on the upper semiconductor chips 230, 240, and 250 based on the virtual horizontal line 500 as shown in FIG. 1A. Based on the virtual horizontal line 500, the upper portion of the semiconductor device may have a relatively higher ratio of metal when compared to the lower portion thereof. Metal has a relatively high thermal expansion coefficient compared to semiconductor devices. Therefore, the upper portion of the semiconductor device has an average thermal expansion coefficient higher than the lower portion thereof. For example, when the temperature of the semiconductor device rises, the upper portion of the semiconductor device may be expanded to a greater degree than when the warpage prevention metal structures 238, 248, and 258 are not present. Therefore, when compared to the absence of the warpage prevention metal structures 238, 248, and 258, the degree of warpage may be reduced, when the warpage prevention metal structures 238, 248, and 258 are present.

As described above, it is possible to reduce the degree of warpage that may occur depending on the semiconductor device by selectively positioning the warpage prevention metal structures 208, 218, 228, 238, 248, and 258 on the semiconductor chip based on the virtual horizontal line 500. When a warpage occurs in the semiconductor device, electrical connections of internal members in the semiconductor device may be disconnected, or damage or defects may occur in the semiconductor chip. Therefore, it is possible to increase the reliability of the semiconductor device by reducing the warpage which may occur in the semiconductor device according to an embodiment of the present inventive concept.

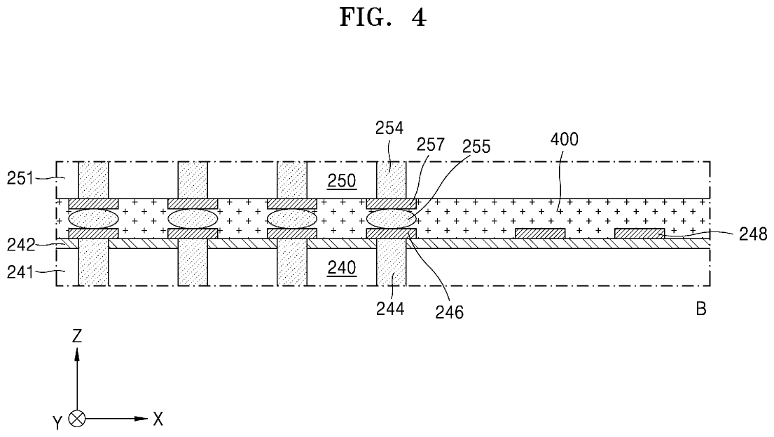

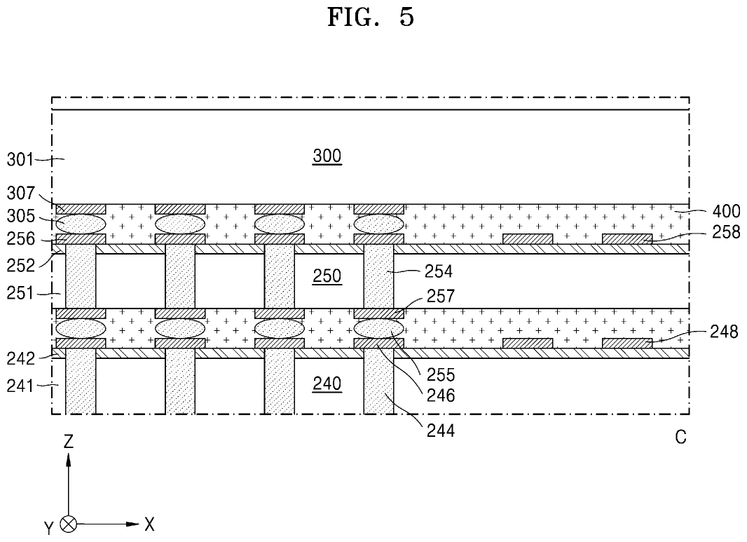

FIG. 4 is an enlarged side cross-sectional view of a portion B, which is portion of the semiconductor device of FIG. 1A, and FIG. 5 is an enlarged side cross-sectional view of a portion C, which is a portion of the semiconductor device of FIG. 1A.

Referring to FIG. 4, in an embodiment the height in the Z-axis direction of the warpage prevention metal structure 248 disposed on the upper surface of the semiconductor chip 240 may be substantially the same as the height in the Z-axis direction of the upper conductive pad 246 disposed on the upper surface of the first TSV 244 of the first semiconductor chip 240. Further, the width in the X-axis direction of the warpage prevention metal structure 248 disposed on the upper surface of the semiconductor chip 240 may be substantially the same as the width in the X-axis direction of the upper conductive pad 246 disposed on the upper surface of the TSV 244. Likewise, referring to FIG. 5, the height and width of the warpage prevention metal structure 258 disposed on the upper surface of the semiconductor chip 250 may be substantially the same as the height in the Z-axis direction and the width in the X-axis direction of the warpage prevention metal structure 258 formed on the upper surface of the TSV 254 of the semiconductor chip 250. The semiconductor chip which is disposed below when considering the relative positions between the semiconductor chips may be referred to as the first semiconductor chip, and the semiconductor chip which is disposed above when considering the relative positions between the semiconductor chips may be referred to as the second semiconductor chip. Each of the first semiconductor chip and the second semiconductor chip may include a plurality of semiconductor chips. The first semiconductor chip is not necessarily limited to only the semiconductor chip 240, and the second semiconductor chip is not necessarily limited to only the semiconductor chip 250.

Referring to FIG. 5, the semiconductor device of FIG. 1A may further include semiconductor chips 200, 210, 220, and 230, and upper conductive pads 106, 206, 216, 226, 236, 246, and 256 disposed on each of the upper surfaces of the TSVs of the semiconductor chips 200, 210, 220, 230, 240, and 250 may be disposed on the same vertical line. For example, the upper conductive pads 106, 206, 216, 226, 236, 246, and 256 disposed on each of the upper surfaces of the TSVs of the semiconductor chips 200, 210, 220, 230, 240, and 250 may overlap each other (e.g., in the Z direction). For example, connection portions formed for mutual electrical connections between the plurality of semiconductor chips 200, 210, 220, 230, 240, and 250 may be disposed on the same vertical line. Also, the warpage prevention metal structures 208, 218, 228, 238, 248, and 258, which may be disposed on the respective upper surfaces of the semiconductor chips 200, 210, 220, 230, 240, and 250, may be disposed on the same vertical line. However, embodiments of the present inventive concept are not necessarily limited thereto and the shapes and sizes of the warpage prevention metal structures 208, 218, 228, 238, 248, and 258 may vary.

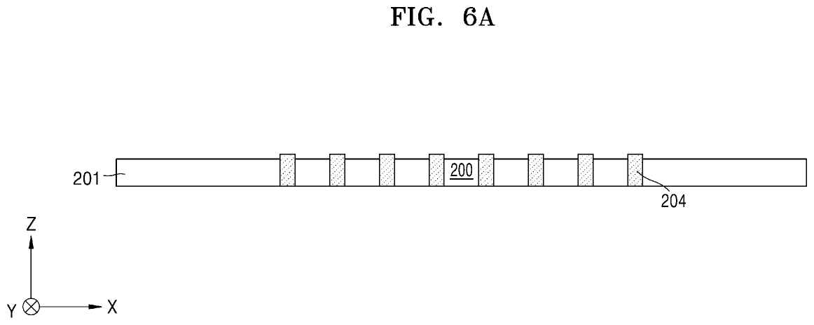

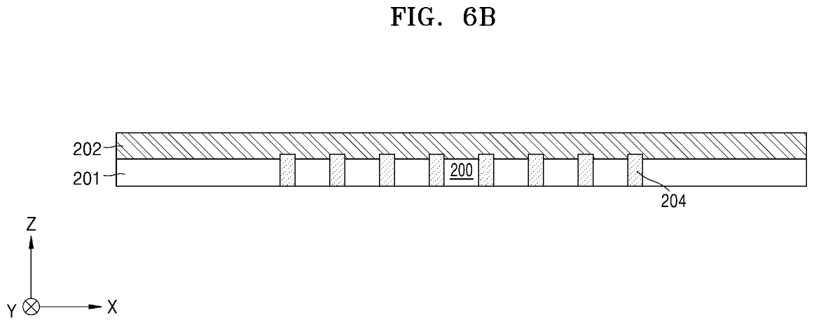

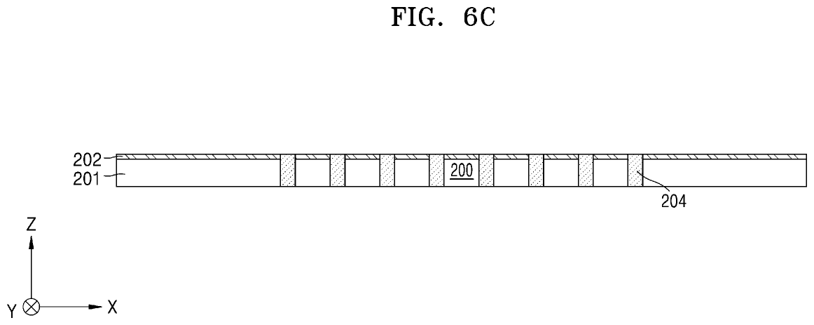

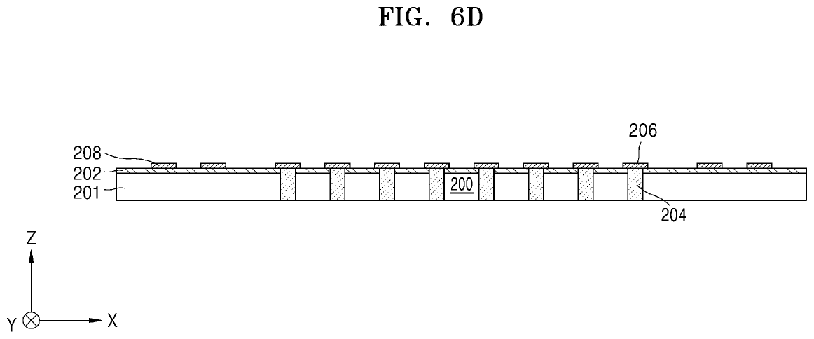

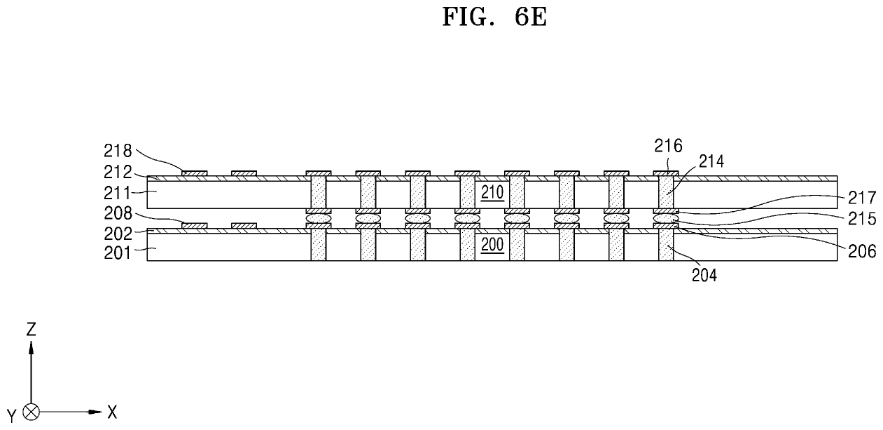

FIGS. 6A to 6E are views illustrating a method of manufacturing a semiconductor device according to embodiments of the present inventive concept.

Referring to FIG. 6A, TSVs 204 may be formed by recessing an upper surface of the semiconductor chip 200. The TSVs 204 may protrude from the upper surface of the semiconductor chip 200 (e.g., in the Z direction). Alternatively, depending on the method of forming the TSVs 204, the TSVs 204 may not protrude. In some embodiments, forming the TSVs 204 by recessing the upper surface of the semiconductor chip 220 may include recessing the upper surface of the semiconductor chip 200 using a dry etching process.

Referring to FIG. 6B, a protective layer 202 covering the TSVs 204 may be formed on (e.g., formed directly thereon in the Z direction) the upper surface of the semiconductor chip 200.

Referring to FIG. 6C, the protective layer 202 may be planarized to expose upper surfaces of the TSVs 204. In an embodiment, the protective layer 202 may be planarized by a chemical mechanical polishing (CMP) process to expose the upper surface of the TSVs 204. However, embodiments of the present inventive concept are not necessarily limited thereto.

Referring to FIG. 6D, upper conductive pads 206 may be formed on the exposed upper surface of the TSVs 204, and each of warpage prevention metal structures 208 having substantially the same height as each of the upper conductive pads 206 may be formed on (e.g., formed directly thereon in the Z direction) the protective layer 202.

In some embodiments, the upper conductive pads 206 and the warpage prevention metal structures 208 may be formed together. Accordingly, each of the upper conductive pads 206 and each of the warpage prevention metal structures 208 may be formed of the same material with substantially the same height.

However, embodiments of the present inventive concept are not necessarily limited thereto. For example, in some embodiments, the warpage prevention metal structures 208 may not be formed in the same shape or material as the upper conductive pads 206. For example, in an embodiment the upper conductive pads 206 and the warpage prevention metal structures 208 may be formed in the same method, but may be formed in a different height or different shape through a separate step, or may be formed of a different material. In an embodiment, the warpage prevention metal structure 208 may be formed first, and then the upper conductive pad 206 may be subsequently formed. However, embodiments of the present inventive concept are not necessarily limited thereto. For example, in an embodiment the upper conductive pad 206 may be formed first, and then the warpage prevention metal structure 208 may be subsequently formed.

Referring to FIG. 6E, a second semiconductor chip 210 including a TSV 214 formed on the same vertical line as each of the TSVs 204 may be arranged on the semiconductor chip 200. In an embodiment, arranging the semiconductor chip 210 on the semiconductor chip 200 may include thermo-compression bonding the second semiconductor chip 210 on the first semiconductor chip 200. Similar to the above-described process, the upper surface of the semiconductor chip 210 is recessed to protrude the TSVs 214. In some embodiments, forming the TSVs 214 by recessing the upper surface of the semiconductor chip 210 may include recessing the upper surface of the semiconductor chip 210 using a dry etching process. A protective layer 212 covering the TSVs 214 is formed on (e.g., formed directly thereon in the Z direction) the upper surface of the semiconductor chip 210. The protective layer 212 may be planarized to expose the upper surface of the TSVs 214. In some embodiments, exposing the upper surface of the TSVs 214 by planarizing the protective layer 212 may include planarizing the protective layer 212 using a chemical mechanical polishing (CMP) process. An upper conductive pad 216 is formed on the exposed upper surface of each of the TSVs 214, and at least one warpage prevention metal structure 218 having a substantially same height as the upper conductive pad 216 is formed on (e.g., formed directly thereon in the Z direction) the protective layer 212. In an embodiment, the forming the upper conductive pad 216 may be formed on the exposed upper surface of the TSV 214, and the forming the warpage prevention metal structure 218 having the substantially same height as the upper conductive pad 216 on the protective layer 212, may include forming a barrier metal layer on a upper surface of the semiconductor chip 210, forming a photoresist pattern to cover a portion where the upper conductive pad 216 and the warpage prevention metal structure 218 are to be formed, and etching the barrier metal layer by using the photoresist pattern as a mask. The respective photoresists for forming a photoresist pattern to cover a portion where the upper conductive pad 216 and the warpage prevention metal structure 218 are to be formed may have the same shape.

In an embodiment, the warpage prevention metal structures 218 may not be formed in the same shape or be composed of a same material as the upper conductive pads 216. As described above, a barrier metal layer may be formed on the upper surface of the semiconductor chip 210, and a photoresist pattern covering a portion where the upper conductive pad 216 is to be formed may be formed. The barrier metal layer may be etched using the photoresist pattern as a mask. Then, the barrier metal layer may be formed on the upper surface of the semiconductor chip 210, and the material of the warpage prevention metal structure 218 may be different from the material of the upper conductive pad 216 by changing the material of the barrier metal layer. The barrier metal layer may be etched by forming a photoresist pattern covering a portion where the warpage prevention metal structures 218 are to be formed, and using the photoresist pattern as a mask. When the shapes of the respective barrier metal layers are changed, the shapes of the upper conductive pad 216 and the warpage prevention metal structure 218 may not be the same. In an embodiment, the order of the above process may be carried out such that the warpage prevention metal structure 218 is first formed, and then the upper conductive pad 216 is subsequently formed.

The semiconductor chips 220, 230, 240, and 250 and the upper semiconductor chip 300 are sequentially formed above the semiconductor chip 210 by the method described in FIGS. 6A to 6E. A thickness (e.g., length in the Z direction) of the upper semiconductor chip 300 may be greater than a thickness of each of the semiconductor chips 200, 210, 220, 230, 240, and 250. In an embodiment, forming the semiconductor chip 230 and the upper semiconductor chip 300 above the semiconductor chip 220 may include thermal compressive bonding the semiconductor chip 230 on the semiconductor chip 220 and then thermal compressive bonding the upper semiconductor chip 300 on the semiconductor chip 230.

In an embodiment, forming the semiconductor chips 220, 230, 240, 250 and the upper semiconductor chip 300 above the semiconductor chip 210 may include forming an under fill material 400 filling a space between the semiconductor chip 200 and the semiconductor chip 210 and an under fill material 400 filling a space between each of the semiconductor chip 220, 230, 240, and 250 and the upper semiconductor chip 300. The under fill material 400 may surround at least a portion of the side surfaces of the semiconductor chips 200, 210, 220, 230, 240, and 250 and at least a portion of a side surface of the upper semiconductor chip 300. In an embodiment, the under fill material 400 may include a nonconductive film (NCF).

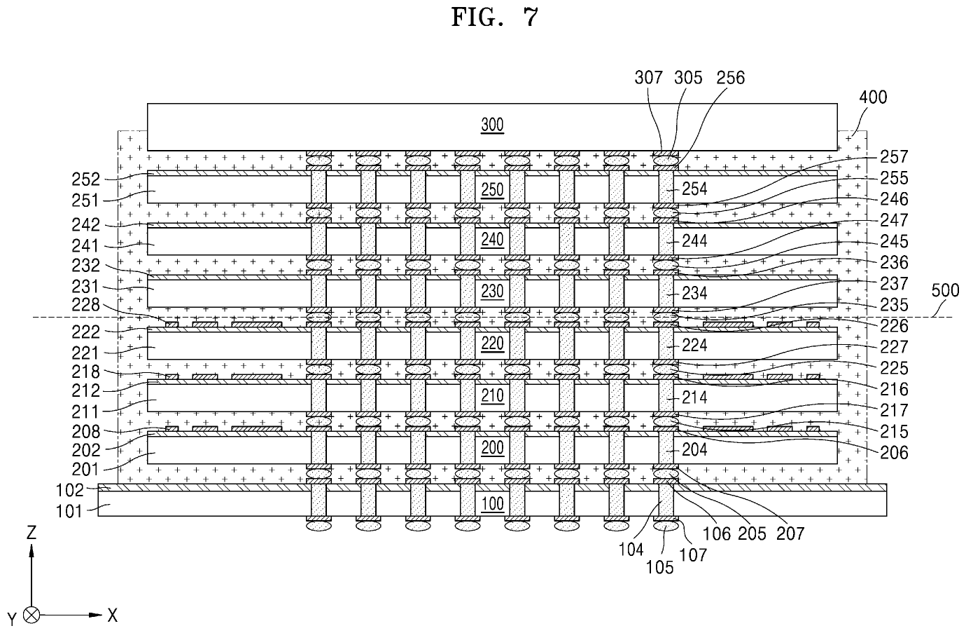

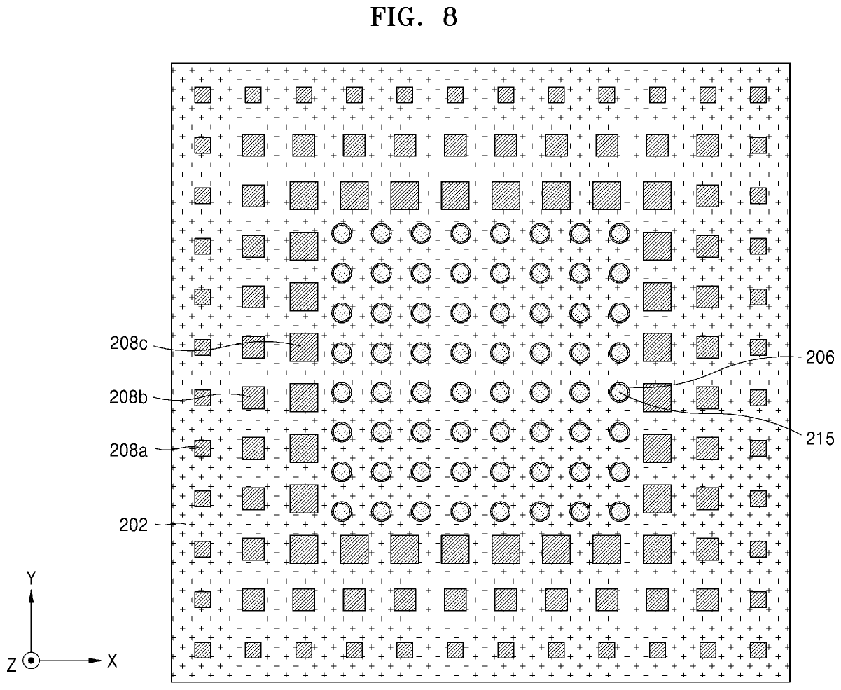

FIG. 7 is a side cross-sectional view illustrating a semiconductor device according to an embodiment of the present inventive concept, and FIG. 8 is a plan view illustrating an X-Y plane between a semiconductor chip 200 and a semiconductor chip 210 when viewed in the −Z-axis direction in the semiconductor device of FIG. 7 according to an embodiment of the present inventive concept.

Referring to FIGS. 7 and 8, the warpage prevention metal structures 208, 218, and 228 may be disposed on the semiconductor chips 200, 210, and 220, respectively, in different areas. When a warpage occurs in the semiconductor chip, more stress may be applied to the central portion of the semiconductor chip relative to the peripheral portion of the semiconductor chip. This is because a relatively smaller transformation may occur in the left and right end portions of the semiconductor device compared to the central portion thereof. Therefore, the shapes of the warpage prevention metal structures 208, 218, and 228 may be arranged such that an area on the X-Y plane or a thickness in the Z-axis direction of each of the warpage prevention metal structures close to the center of the semiconductor chip are greater than the warpage prevention metal structure farther from the center. Referring to FIG. 7, three warpage prevention metal structures 208, 218, and 228 may be disposed on each of the left and right side surfaces of the semiconductor chip. In addition, the length of the warpage prevention metal structure closest to each of the TSV 204, 214, and 224 in the X-axis direction may be arranged to be greater than the length of the other warpage prevention metal structures to provide a large area of the warpage prevention metal structure relative to the X-Y plane. An area of the warpage prevention metal structure 208a located at a distance farther from the TSV 204 in the X-Y plane may be less than an area of the warpage prevention metal structure 208c located at a distance closer to the TSV 204 in the X-Y plane. An area of the warpage prevention metal structure 208b located between the warpage prevention metal structure 208a and the warpage prevention metal structure 208c in the X-Y plane may be larger than the area of the warpage prevention metal structure 208a and smaller than the area of the warpage prevention metal structure 208c. The above-described warpage prevention metal structure may be disposed on the semiconductor chips 210 and 220, and a redundant description thereof will be omitted. The arrangement, number and shape of the warpage prevention metal structures 208, 218, and 228 are not necessarily limited to those shown in an embodiment of FIG. 7. In addition, as previously described, the warpage prevention metal structure 208 may be disposed at an upper portion or a lower portion with respect to the virtual horizontal line 500.

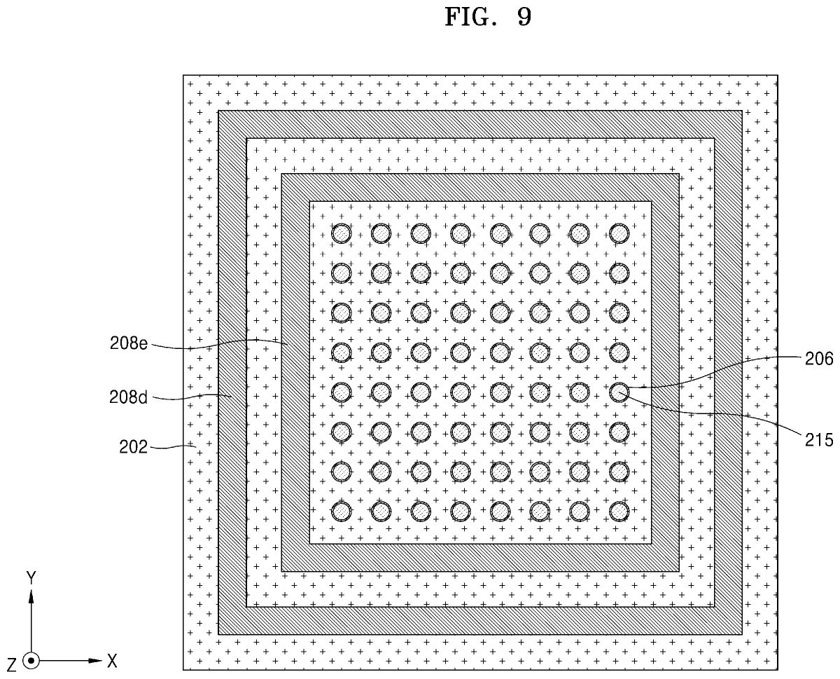

FIG. 9 is a plan view of a semiconductor device according to an embodiment of the present inventive concept when viewed in the −Z-axis direction at the same position as shown in FIG. 8. Referring to FIG. 9, warpage prevention metal structures 208d and 208e may be disposed on the protective layer 202 disposed on the upper surface of the semiconductor chip 200 (FIG. 7). The TSV 204 (FIG. 7) may be disposed at a lower end of the upper conductive pad 206 in the Z-axis direction. The warpage prevention metal structure 208e may be arranged in a frame shape surrounding the peripheral circumference of each of the TSVs 204 (FIG. 7) formed in the central portion of the semiconductor chip 200 (FIG. 7). The frame shape may extend in the X and Y directions. The warpage prevention metal structure 208d may be arranged in a frame shape (e.g., extending in the X and Y directions) surrounding the TSVs 204 formed in the central portion of the semiconductor chip 200 and the frame-shaped warpage prevention metal structure 208e surrounding the TSVs 204. In an embodiment, the warpage prevention metal structures 208d and 208e in FIG. 9 have a rectangular shape and may have a shape similar to the shape of the circumference of the semiconductor chip 200. For example, the warpage prevention metal structures 208d and 208e may each have two sides in the X-axis direction and two sides in the Y-axis direction. Therefore, even if the direction in which the warpage occurs is not uniform, the warpage may be reduced through the warpage prevention metal structures 208d and 208e. In addition, as previously described the warpage prevention metal structures 208d and 208e may be disposed at an upper portion or a lower portion with respect to the virtual horizontal line 500. The shape, thickness, and length of the warpage prevention metal structures 208d and 208e described above are not necessarily limited to an embodiment shown in FIG. 9 and may vary.

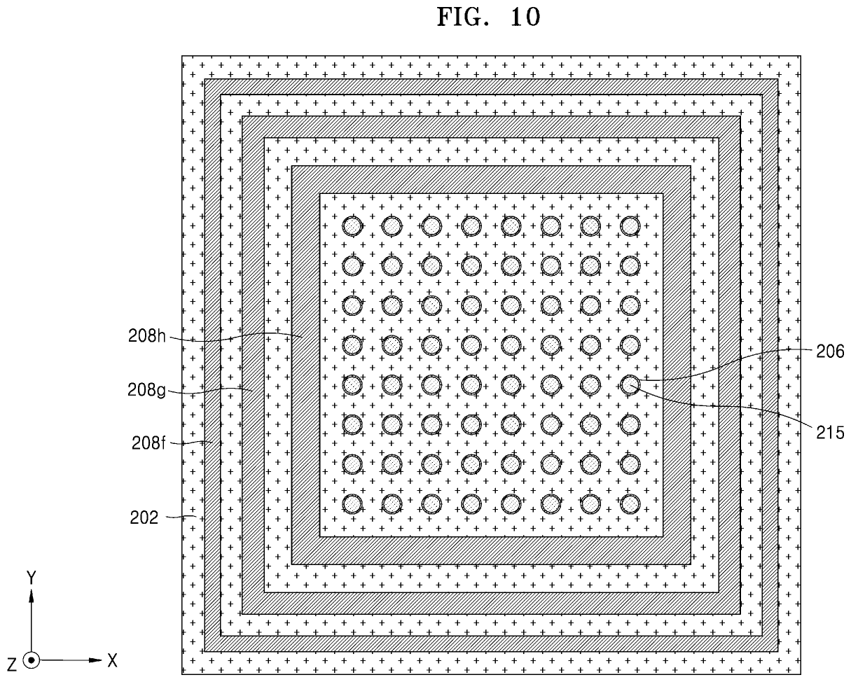

FIG. 10 is a plan view of a semiconductor device according to an embodiment of the present inventive concept when viewed in the −Z-axis direction at the same position as shown in FIG. 8. Referring to FIG. 10, warpage prevention metal structures 208f, 208g, and 208h may be disposed on the protective layer 202 disposed on the upper surface of the semiconductor chip 200 (FIG. 7). The TSV 204 (FIG. 7) may be disposed at a lower portion of the upper conductive pad 206 in the Z-axis direction. The warpage prevention metal structure 208h may be arranged in a frame shape surrounding the periphery of each of the TSVs 204 (FIG. 7) disposed in the central portion of the semiconductor chip 200 (FIG. 7). The warpage prevention metal structure 208g may be arranged in a frame shape surrounding the TSVs 214 disposed in the central portion of the semiconductor chip 200 and the frame-shaped warpage prevention metal structure 208h surrounding the TSVs 214. The warpage prevention metal structure 208f may be arranged in a frame shape surrounding the TSVs 204 disposed in the central portion of the semiconductor chip 200 and the frame-shaped warpage prevention metal structure 208g surrounding the TSVs 204. The warpage prevention metal structure 208h may have a greater area in the X-Y plane than the warpage prevention metal structure 208g. The warpage prevention metal structure 208g may have a greater area in the X-Y plane than the warpage prevention metal structure 208f. The warpage prevention metal structures 208f, 208g, 208h in FIG. 10 may have a rectangular shape and may have a shape similar to the shape of the circumference of the semiconductor chip 200. For example, the warpage prevention metal structures 208f, 208g, and 208h may each have two sides in the X-axis direction and two sides in the Y-axis direction. Therefore, even if the direction in which the warpage occurs is not uniform, the warpage may be reduced through the warpage prevention metal structures 208f, 208g, and 208h. In addition, as previously described the warpage prevention metal structures 208f, 208g, and 208h may be disposed at an upper portion or a lower portion with respect to the virtual horizontal line 500. The shape, thickness, and length of the warpage prevention metal structures 208f, 208g, and 208h described above are not necessarily limited to an embodiment shown in FIG. 10 and may vary.

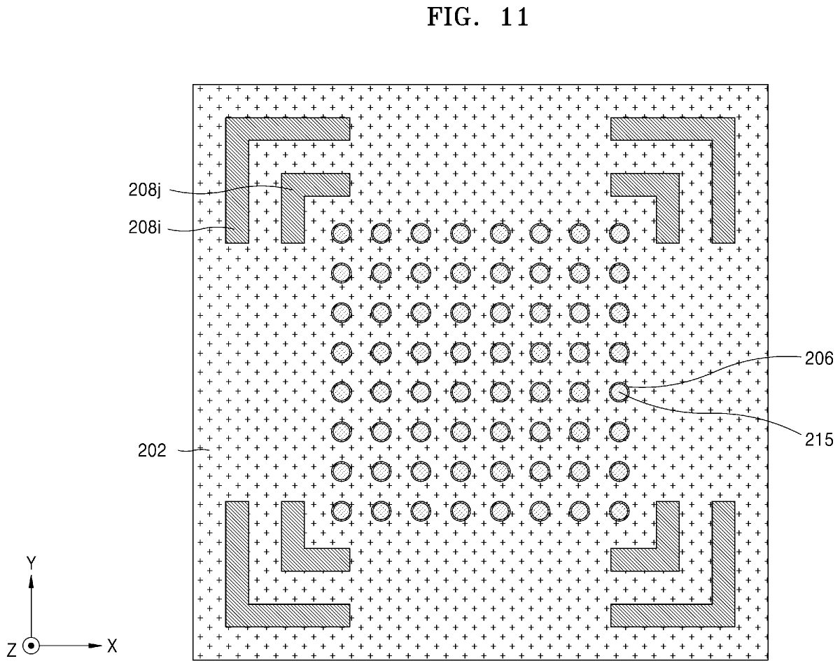

FIG. 11 is a plan view of a semiconductor device according to an embodiment of the present inventive concept when viewed in the −Z-axis direction at the same position as shown in FIG. 8. Referring to FIG. 11, warpage prevention metal structures 208i and 208j may be disposed on the protective layer 202 disposed on the upper surface of the semiconductor chip 200 (FIG. 7). The TSV 204 (FIG. 7) may be disposed at a lower portion of the upper conductive pad 206 in the Z-axis direction. The warpage prevention metal structure 208j may be disposed around the TSVs 204 disposed in the central portion of the semiconductor chip 200. The warpage prevention metal structure 208j may have an L-shape similar to the shape of the corner of the semiconductor chip 200. The warpage prevention metal structure 208j may be disposed between each of four corners of the semiconductor chip 200 and each of the TSVs 204. The warpage prevention metal structure 208i may have an L-shape similar to the shape of the corner of the semiconductor chip 200. The warpage prevention metal structure 208i may be disposed between each of four corners of the semiconductor chip 200 and the warpage prevention metal structure 208j. The warpage prevention metal structure 208i may have a greater area in the X-Y plane than the warpage prevention metal structure 208j. In addition, as previously described the warpage prevention metal structures 208i and 208j may be disposed at an upper portion or a lower portion with respect to the virtual horizontal line 500. The shape, thickness, and length of the warpage prevention metal structures 208i and 208j are not necessarily limited to an embodiment shown in FIG. 11 and may vary.

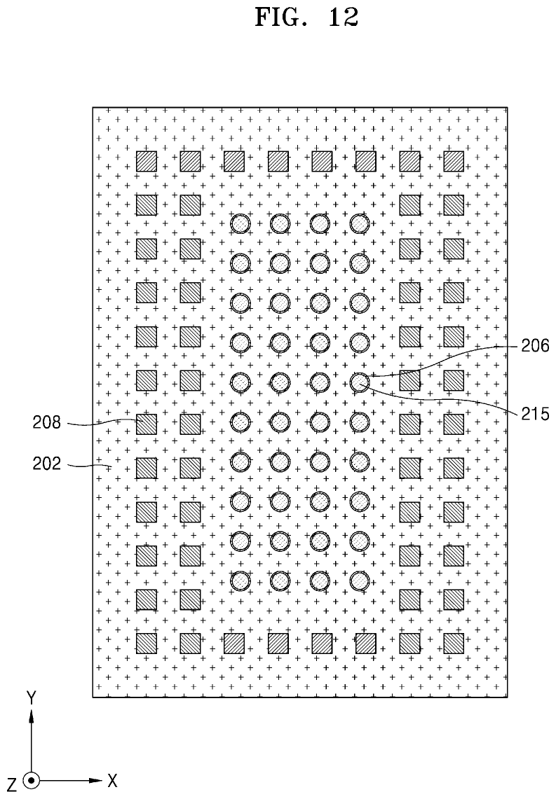

FIG. 12 is a plan view of a semiconductor device according to an embodiment of the present inventive concept when viewed in the −Z-axis direction at the same position as shown in FIG. 8. Referring to FIG. 12, the warpage prevention metal structure 208 may be disposed on a semiconductor chip of an HBM including a TSV array among semiconductor devices. The TSV array may refer to a region in which TSVs are aligned and concentrated in a specific region on the semiconductor chip. Hereinafter, FIGS. 12 to 17 illustrate embodiments of the present inventive concept for a semiconductor device including a TSV array. The TSV 204 (FIG. 7) may be disposed at a lower portion of the upper conductive pad 206 in the Z-axis direction. The warpage prevention metal structure 208 may be arranged along the shape of the circumference of the semiconductor chip in a rectangular shape around the TSVs 204 constituting the TSV array. In addition, as previously described the warpage prevention metal structures 208 may be disposed at an upper portion or a lower portion with respect to the virtual horizontal line 500. The shape, thickness, and length of the warpage prevention metal structures 208i and 208j are not necessarily limited to an embodiment shown in FIG. 12 and may vary.

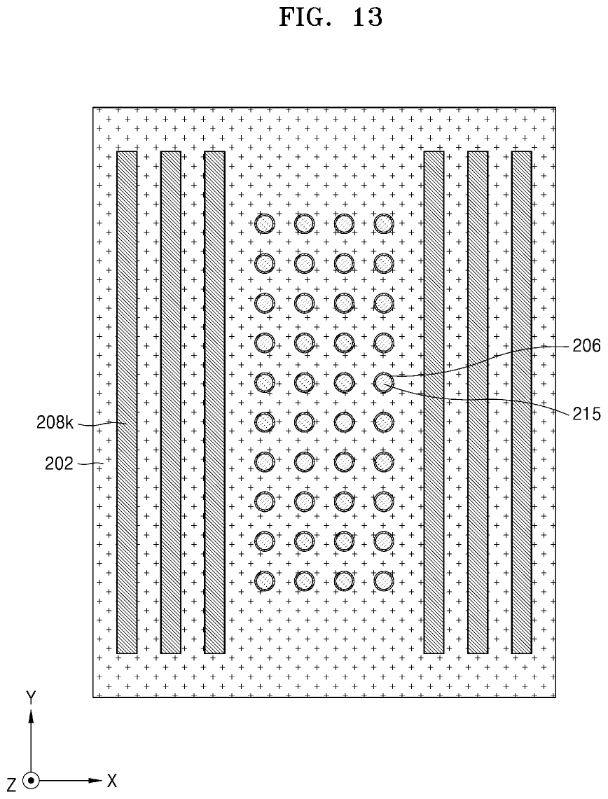

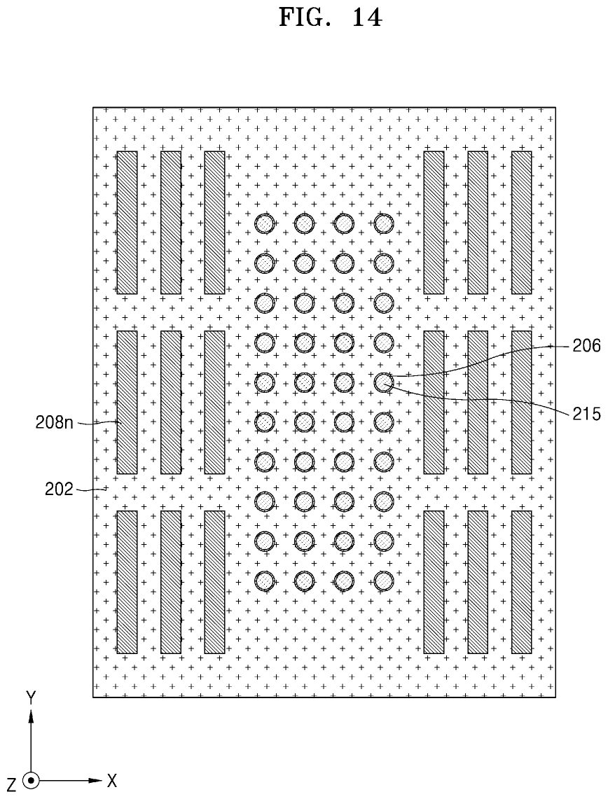

FIGS. 13 and 14 are plan views of a semiconductor device according to embodiments of the present inventive concept when viewed in the −Z-axis direction at the same position as shown in FIG. 8. Referring to FIG. 13, the warpage prevention metal structure 208k may be arranged such that the length in one direction (e.g., the Y-axis direction) is longer than the length in the other direction (e.g., the X-axis direction). For example, the warpage prevention metal structure 208k may have a long rod shape. The TSV 204 (FIG. 7) may be disposed at a lower portion of the upper conductive pad 206 in the Z-axis direction. A warpage prevention metal structure 208k may be disposed on a surface of a portion where TSV is not formed around the TSV array. As shown in FIG. 13, one or more warpage prevention metal structures 208k may be disposed on the left or right side in the X-axis direction based on the TSVs 204. For example, FIG. 13 shows three warpage prevention metal structures 208k disposed on both the left and the right side in the X-axis direction based on the TSVs 204. The warpage prevention metal structures 208k are arranged in the X-axis direction. However, embodiments of the present inventive concept are not necessarily limited thereto.

Referring to FIG. 14, the warpage prevention metal structure 208n may be arranged such that a length in one direction (e.g., the Y-axis direction) is longer than a length in another direction (e.g., the X-axis direction), like the warpage prevention metal structure 208k in FIG. 13. However, two or more warpage prevention metal structures 208n may be arranged along one direction (e.g., the Y-axis direction). One or more warpage prevention metal structures 208n may be disposed on the left or right side in the X-axis direction based on the TSVs 204 (FIG. 7). For example, FIG. 14 shows nine warpage prevention metal structures 208n arranged in the X and Y directions on both the left and right side in the X-axis direction of the TSVs 204. However, embodiments of the present inventive concept are not necessarily limited thereto.

As previously described, the warpage prevention metal structures 208k and 208n may be disposed at an upper portion or a lower portion with respect to the virtual horizontal line 500. The shape, thickness, and length of the warpage prevention metal structures 208k and 208n are not necessarily limited by embodiments shown in FIGS. 13 and 14.

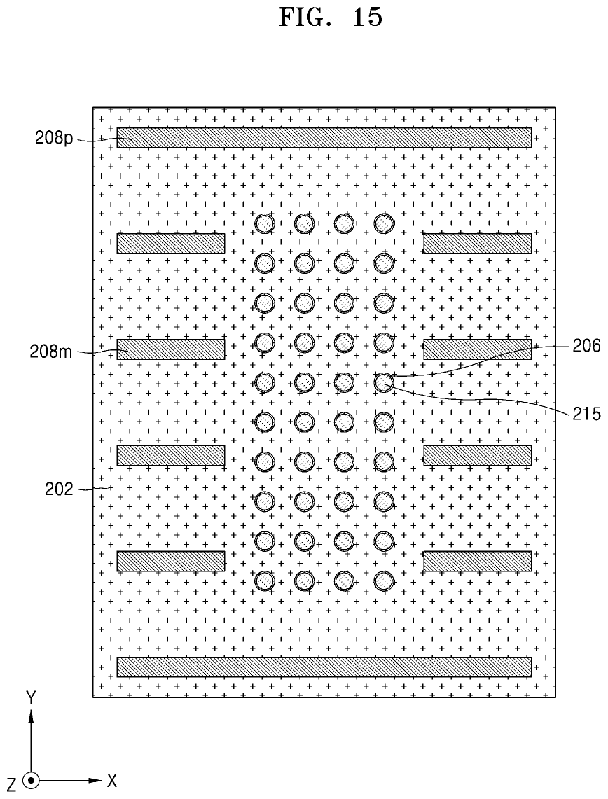

FIG. 15 is a plan view of a semiconductor device according to an embodiment of the present inventive concept when viewed in the −Z-axis direction at the same position as shown in FIG. 8. Referring to FIG. 15, the warpage prevention metal structure 208m may be arranged such that the length in the one direction (e.g., the X-axis direction) is longer than the length in another direction (e.g., the Y-axis direction). Based on the X-axis direction, the warpage prevention metal structures 208m may be arranged at regular intervals in the Y-axis direction at portions where no TSV is formed on the left and right sides of the TSV array. For example, as shown in FIG. 15 three warpage prevention metal structures 208m may be arranged at regular intervals in the Y-axis direction at both left and right sides of the TSV array. However, embodiments of the present inventive concept are not necessarily limited thereto. The TSV 204 (FIG. 7) may be disposed at a lower portion of the upper conductive pad 206 in the Z-axis direction. On the protective layer 202 disposed on the semiconductor chip 200, a warpage prevention metal structure 208p may be disposed on the upper or lower surface of the TSV array where no TSV is formed in the Y-axis direction. The warpage prevention metal structure 208p may be arranged to have a longer length in one direction (e.g., the X-axis direction) than the warpage prevention metal structure 208m. For example as shown in FIG. 15, one warpage prevention metal structure 208p may be arranged on an upper side of the semiconductor chip 200 in the Y direction and one warpage prevention metal structure 208p may be arranged on a lower side of the semiconductor chip 200 in the Y direction. However, embodiments of the present inventive concept are not necessarily limited thereto. As previously described, the warpage prevention metal structure 208m may be disposed at an upper portion or a lower portion with respect to the virtual horizontal line 500. The shape, thickness, and length of the warpage prevention metal structure 208m are not necessarily limited to an embodiment shown in FIG. 15 and may vary.

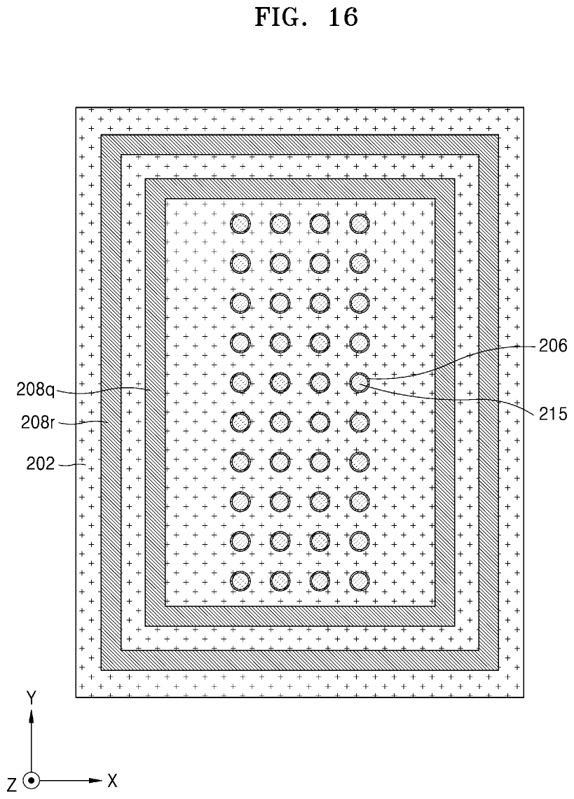

FIG. 16 is a plan view of a semiconductor device according to an embodiment of the present inventive concept when viewed in the −Z-axis direction at the same position as shown in FIG. 8. Referring to FIG. 16, warpage prevention metal structures 208r and 208q may be disposed on the protective layer 202 formed on the upper surface of the semiconductor chip 200 (FIG. 7). The TSV 204 (FIG. 7) may be disposed at a lower portion of the upper conductive pad 206 in the Z-axis direction. The warpage prevention metal structure 208q may be arranged in a frame shape surrounding the peripheral portions of the TSVs 204 of the TSV array described above. The warpage prevention metal structure 208r may be arranged in a frame shape surrounding the TSV array and the frame-shaped warpage prevention metal structure 208q. The warpage prevention metal structures 208q and 208r in FIG. 16 have a rectangular shape and may have a shape similar to the shape of the circumference of the semiconductor chip 200 (FIG. 7). For example, the warpage prevention metal structures 208q and 208r may each have two sides in the X-axis direction and two sides in the Y-axis direction. Therefore, even if the direction in which the warpage occurs is not uniform, the warpage may be reduced through the warpage prevention metal structures 208q and 208r. In addition, as previously described, the warpage prevention metal structures 208q and 208r may be disposed at an upper portion or a lower portion with respect to the virtual horizontal line 500. The shape, thickness, and length of the warpage prevention metal structures 208q and 208r described above are not necessarily limited to an embodiment shown in FIG. 16 and may vary.

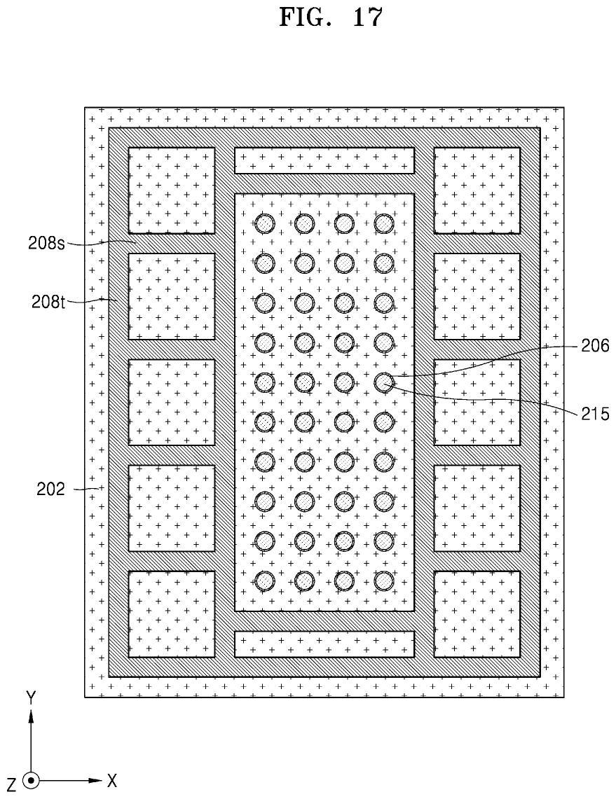

FIG. 17 is a plan view of a semiconductor device according to an embodiment of the present inventive concept when viewed in the −Z-axis direction at the same position as shown in FIG. 8. Referring to FIG. 17, the warpage prevention metal structure may be arranged in a lattice shape surrounding the TSVs 204 constituting the TSV array. The lattice shape may be formed in an arrangement of rectangles including a warpage prevention metal structure 208t in one direction (e.g., the Y-axis direction) and a warpage prevention metal structure 208s in the other direction (e.g., the X-axis direction). The size and shape of the square may be arranged differently depending on the shape of the surface of the semiconductor chip and the position of the TSV. In addition, as previously described, the warpage prevention metal structures 208s and 208t may be disposed at an upper portion or a lower portion with respect to the virtual horizontal line 500. The shape, thickness, and length of the warpage prevention metal structures 208s and 208t described above are not necessarily limited to an embodiment shown in FIG. 17 and may vary.

While the present inventive concept has been particularly shown and described with reference to embodiments thereof, it will be understood that various changes in form and details may be made therein without departing from the spirit and scope of the present inventive concept.

What is claimed is:

1. A semiconductor device comprising:
a first semiconductor chip having a first through silicon via (TSV);
a second semiconductor chip arranged on the first semiconductor chip and including a second TSV positioned on a same vertical line as the first TSV;
a conductive pad disposed on each of the first TSV and the second TSV, the conductive pad electrically connecting the first semiconductor chip and the second semiconductor chip to each other; and
a warpage prevention metal structure disposed on an upper surface of the first semiconductor chip or an upper surface of the second semiconductor chip.

2. The semiconductor device of claim 1, wherein the warpage prevention metal structure surrounds a peripheral circumference of the first TSV or the second TSV.

3. The semiconductor device of claim 2, wherein the warpage prevention metal structure is arranged in a frame shape.

4. The semiconductor device of claim 1, further comprising a protective layer on upper surfaces of each of the first semiconductor chip and the second semiconductor chip, wherein the warpage prevention metal structure is disposed directly on the protective layer.

5. The semiconductor device of claim 1, wherein the warpage prevention metal structure is electrically insulated from the first semiconductor chip and the second semiconductor chip.

6. The semiconductor device of claim 1, wherein the warpage prevention metal structure has a substantially same height as the conductive pad.

7. The semiconductor device of claim 1, wherein the warpage prevention metal structure is composed of a same material as the conductive pad.

8. The semiconductor device of claim 1, wherein the warpage prevention metal structure is composed of a different material or has a different size from that of the conductive pad.

9. The semiconductor device of claim 1, further comprising an upper semiconductor chip arranged on the second semiconductor chip, the upper semiconductor chip having a thickness greater than thicknesses of each of the first semiconductor chip and the second semiconductor chip.

10. The semiconductor device of claim 9, further comprising an under fill material filling a space among the first semiconductor chip, the second semiconductor, and the upper semiconductor chip, the under fill material surrounding a periphery thereof.

11. The semiconductor device of claim 1, further comprising a conductive bump arranged between the conductive pad disposed on an upper end of the first TSV and the conductive pad disposed on a lower end of the second TSV, the conductive bump is electrically connected to the conductive pad on each of the first TSV and the second TSV.

12. A semiconductor device comprising:
a plurality of inner substrates including semiconductor devices;
a through silicon via (TSV) arranged to vertically penetrate each of the plurality of inner substrates;
a protective layer disposed on an upper surface of each of the plurality of inner substrates, the protective layer surrounding a side surface of the TSV;
a conductive pad arranged on the TSV; and
a warpage prevention metal structure disposed on the protective layer of some of the plurality of inner substrates, the warpage prevention metal structure is electrically insulated from the semiconductor devices of the plurality of inner substrates.

13. The semiconductor device of claim 12, further comprising an upper substrate arranged on an upper portion of the plurality of inner substrates, the upper substrate is electrically connected to an uppermost inner substrate among the plurality of inner substrates through the conductive pad, the upper substrate has a thickness greater than thicknesses of each of the plurality of inner substrates.

14. The semiconductor device of claim 12, wherein the warpage prevention metal structure is disposed at a substantially same height and is composed of a same material as the conductive pad.

15. The semiconductor device of claim 12, wherein:
a plurality of warpage prevention metal structures is disposed on the protective layer of some of the plurality of inner substrates; and
an area of each of the plurality of warpage prevention metal structures decreases as a distance to a circumference of some of the plurality of inner substrates decreases.

16. The semiconductor device of claim 12, wherein the warpage prevention metal structure is arranged on an upper inner substrate or a lower inner substrate with respect to a virtual horizontal line that divides the plurality of inner substrates in a vertical direction.

17. The semiconductor device of claim 12, wherein:
the warpage prevention metal structure includes a plurality of warpage prevention metal structures; and
each of the plurality of warpage prevention metal structures has a long rod shape in a first direction, the plurality of warpage prevention metal structures is arranged parallel to each other in a second direction perpendicular to the first direction.

18. The semiconductor device of claim 12, wherein:
the warpage prevention metal structure includes a plurality of warpage prevention metal structures; and
each of the plurality of warpage prevention metal structures extends in a first direction or a second direction perpendicular to the first direction,
wherein the plurality of warpage prevention metal structures has a grid shape and is arranged along a shape of the plurality of inner substrates around a TSV circumference.

19. The semiconductor device of claim 12, further comprising an under fill material surrounding the conductive pad and the warpage prevention metal structure, the under fill material filling a space among the plurality of inner substrates.

20. A semiconductor device comprising:
a plurality of inner substrates including semiconductor devices;
a through silicon via (TSV) arranged to vertically penetrate each of the plurality of inner substrates;
a protective layer disposed on an upper surface of each of the plurality of inner substrates, the protective layer surrounding a side surface of the TSV;
a conductive pad disposed on the TSV;
a warpage prevention metal structure disposed on the protective layer of an upper inner substrate or a lower inner substrate based on a virtual horizontal line dividing the plurality of inner substrates in a vertical direction, the warpage prevention metal structure is electrically insulated from the semiconductor devices of the plurality of inner substrate; and
an upper substrate arranged on an upper portion of each of the plurality of inner substrates, the upper substrate is electrically connected to an uppermost inner substrate among the plurality of inner substrates through the conductive pad, the upper substrate has a thickness greater than thicknesses of each of the plurality of inner substrates.
